(19) United States
(12) Patent Application Publication
(10) Pub. No.: US 2006/0145158 A1
(43) Pub. Date: Jul. 6, 2006

(54) Poly-crystalline silicon thin film transistor

(75) Inventors: Takashi Noguchi, Seongnam-si (KR); Huaxiang Yin, Yongin-si (KR); Ji-sim Jung, Incheon-si (KR); Wenxu Xianyu, Yongin-si (KR); Jang-yeon Kwon, Seongnam-si (KR); Yong-han Roh, Suwon-si (KR); Suk-won Jeong, Suwon-si (KR); Seong-hoon Jeong, Masan-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRONICS CO., LTD., Suwon-si (KR)

(21) Appl. No.: 11/322,235

(22) Filed: Jan. 3, 2006

(30) Foreign Application Priority Data
Jan. 4, 2005 (KR) 10-2005-0000381

(51) Int. Cl. H01L 29/76

(52) U.S. Cl. 257/66

(57) ABSTRACT

Provided is a silicon thin film transistor (TFT) including: a substrate; a silicon channel layer formed on the substrate with a source and a drain on both sides thereof; a gate insulating layer formed on the silicon channel layer; and a gate formed on the gate insulating layer, wherein the gate insulating layer has a structure including an HfOₓ film. The TFT has a low leakage current.

### CROSS-REFERENCE TO RELATED PATENT APPLICATIONS

Priority is claimed to Korean Patent Application No. 10-2005-0000381, filed on Jan. 4, 2005, in the Korean Intellectual Property Office, the disclosure of which is incorporated herein in its entirety by reference.

### BACKGROUND OF THE INVENTION

1. Field of the Disclosure

The present disclosure relates to a silicon thin film transistor (TFT) having reduced leakage current.

2. Description of the Related Art

Polycrystalline silicon (poly-Si) has higher mobility than amorphous Si (a-Si), and thus can be applied to flat panel display devices and various electronic devices such as solar batteries.

In general, in order to obtain high quality poly-Si crystalline, a material which is resistant to heat, such as glass, is used. When manufacturing poly-Si crystalline on a heat-resistant material, such as glass, high-temperature a-Si deposition methods, such as chemical vapor deposition (CVD), plasma enhanced CVD (PECVD), etc., are used. The maximum size of crystalline grains which can be obtained using such conventional methods is about 3000-4000 Å, and it is difficult to obtain crystalline grains larger than the size using the conventional methods. Therefore, there is a need to develop a technique of fabricating poly-Si having a larger particle diameter.

Recently, a method of forming a poly-Si electronic device on a plastic substrate has been researched. In order to prevent thermal deformation of plastic, when manufacturing a polysilicon electronic device, it is inevitable to use low-temperature processes, such as sputtering. Such a low-temperature process is also required to prevent thermal impact on a substrate and further to suppress processing defects occurring during a high-temperature process for manufacturing a device. Although the plastic substrate is weak to heat, due to the advantages of lightweight, flexibility, and durability, and thus, has been researched in recent years as a substrate for flat panel display devices.

Carry et. al, (U.S. Pat. No. 5,817,550) suggests a method of preventing damage of a plastic substrate when manufacturing a silicon channel in the plastic substrate.

SiO₂ used for a gate insulating layer of a polycrystalline silicon TFT has a limited mutual conductance (gm) of about 3.8. The gate insulating layer has a large leakage current and a low breakdown voltage, and thus cannot be used in a low-temperature polysilicon (LTPS) TFT.

The gate insulating layer, which is an essential element of a TFT, greatly and directly affects on operation characteristics of the TFT. Therefore, research on the gate insulating layer has been performed in various aspects to develop materials and processes suitable for the gate insulating layer of a next generation TFT. In particular, a new material that can minimize a defect, i.e., an interface trap, occurring in the interface between a polycrystalline or amorphous Si substrate and the gate insulating layer to increase the transconductance and the breakdown voltage of the TFT, and the development of a process for stably growing the material are required. In addition, a technology for improving the current driving performance using a material having a larger dielectric constant than SiOx used for a conventional gate insulating layer and reducing the hysteresis characteristics by minimizing defects in the gate insulating layer is required. HfO₂ is a material satisfying the above requirements. However, HfO₂ causes a large leakage current because it exists in crystalline phase at a high temperature.

The present disclosure relates to a TFT including an ultra thin SiO₂ film underneath an HfO₂ film to reduce the leakage current caused from HfO₂. The TFT according to the present disclosure utilizes good insulating characteristics of the SiO₂ film and the high dielectric characteristic of the HfO₂ film.

### SUMMARY OF THE DISCLOSURE

The present disclosure provides a polycrystalline silicon thin film transistor (TFT) having improved interface properties and a low leakage current.

According to an aspect of the present invention, there is provided a TFT comprising: a substrate; a silicon channel layer formed on the substrate with a source and a drain on both sides thereof; a gate insulating layer formed on the silicon channel layer; and a gate formed on the gate insulating layer, wherein the gate insulating layer includes an HfOₓ film.

The gate insulating layer may include a HfOₓ film and a SiO₂ film. The HfOₓ film is a highly dielectric material and may be formed through a low temperature process at 500□ or less. The gate insulating layer may have a thickness of 100 nm or less. The substrate may be a silicon, glass, or plastic substrate.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view of a thin film transistor (TFT) according to an embodiment of the present invention;

FIGS. 2A through 2L are schematic sectional views for explaining a method of manufacturing the TFT of FIG. 1;

FIG. 3 is a graph of capacitance characteristics of a gate insulating layer according to the present disclosure and a gate insulating layer as a comparative example; and

FIG. 4 is a graph of leakage current characteristics of the gate insulating layer according to the present disclosure and the gate insulating layer as a comparative example.

### DETAILED DESCRIPTION OF EXEMPLARY EMBODIMENTS

Hereinafter, embodiments of a poly crystalline silicon thin film transistor (TFT) according to the present invention will be described in detail with reference to the accompanying drawings.

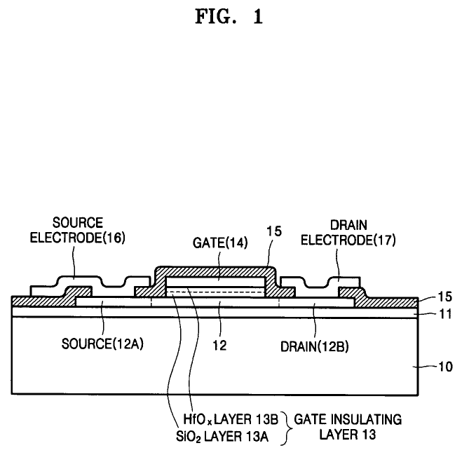

FIG. 1 is a schematic cross-sectional view of a polycrystalline silicon TFT according to an embodiment of the present invention.

Referring to FIG. 1, an insulating layer 11 is formed on a substrate 10, which is made of silicon, glass, or plastic, and a silicon channel layer 12 is disposed on the insulating layer 11. A source region 12a and a drain region 12b are formed on both sides of the silicon channel layer 12 by doping. A gate insulating layer 13 is formed on the silicon channel layer 12, and a gate 14 is formed in a center portion of the gate insulating layer 13. An interlayer dielectric (ILD) 15 is formed on the gate 14. The ILD 15 includes openings in regions corresponding to the source region 12a and the drain region 12b. A source electrode 16 is connected to the source region 12a, which is a polycrystalline silicon region, and a drain electrode 17 is connected to the drain region 12b, which is a polycrystalline silicon.

The gate insulating layer 13 includes a SiO₂ film 13a, which is a lower layer, and a HfOₓ film 13b, which is an upper layer formed on the SiO₂ film 13a.

Hereinafter, a method of fabricating the TFT according to the present disclosure will be described with reference to accompanying drawings.

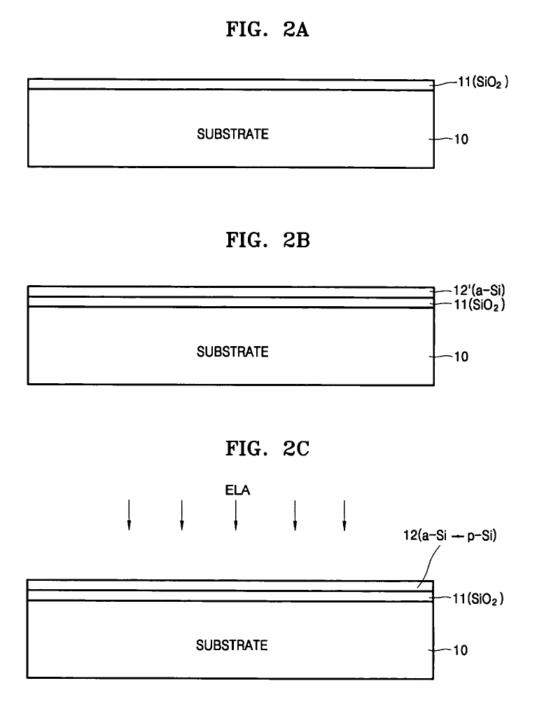

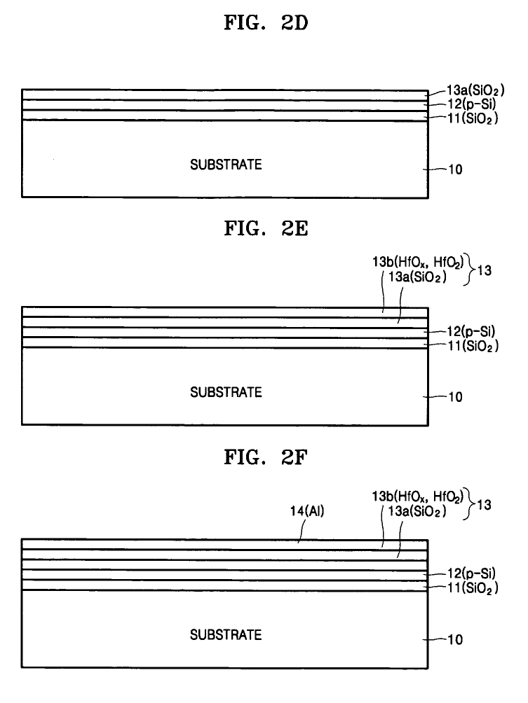

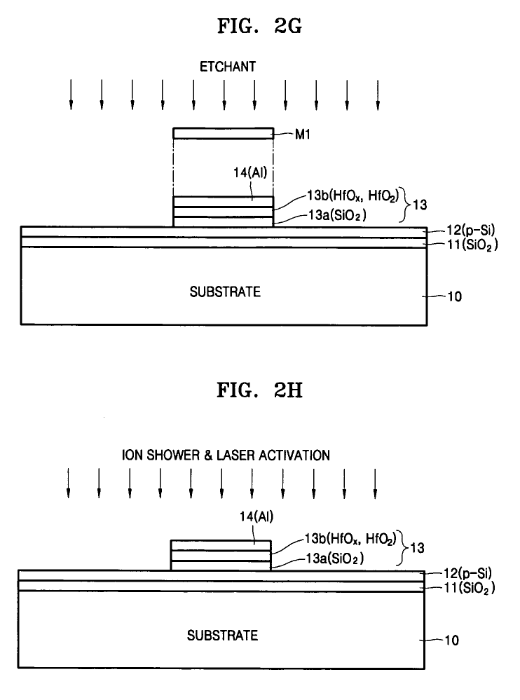

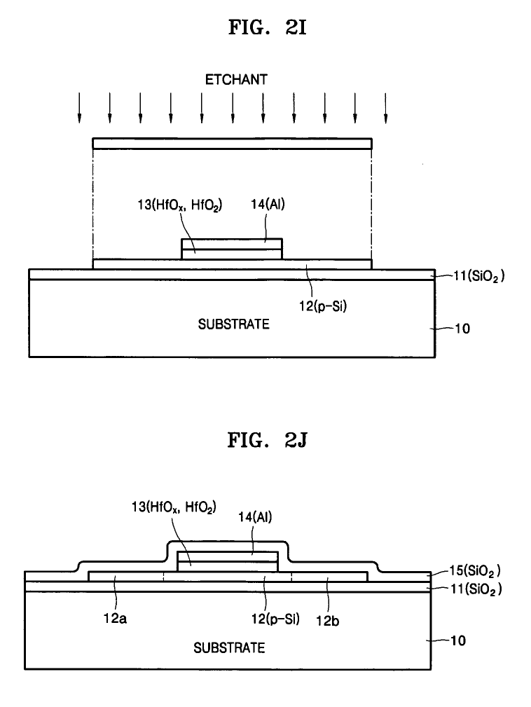

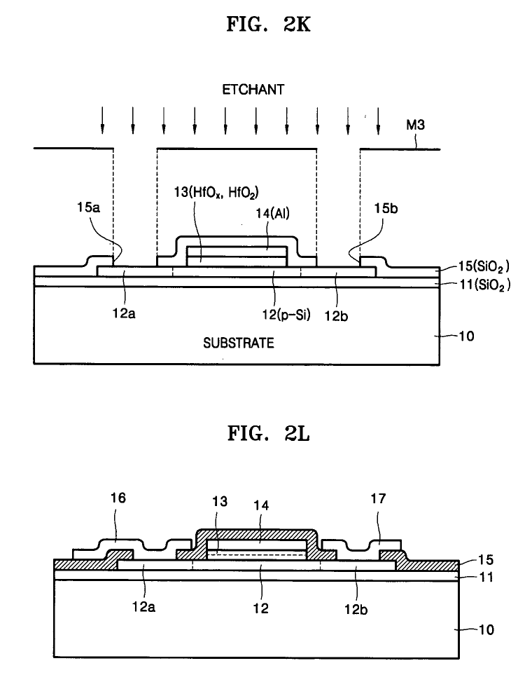

Referring to FIG. 2A, a substrate 10, which can be a silicon water or a glass or plastic substrate, is prepared to form a polycrystalline silicon film thereon. A SiO₂ film 11 for electrical insulation is formed on the substrate 10. When a silicon wafer is used as the substrate 10, the silicon wafer has a natural oxide film.

Referring to FIG. 2B, an amorphous silicon (a-Si) film 12′ is formed on the insulating layer 11 of the substrate 10. The a-Si film 12′ is formed using physical vapor deposition (PVD), such as a sputtering method. In a sputtering process enabling low-temperature deposition, a rare gas, for example, Ar gas, is used as a sputtering gas. The thickness of the a-Si film 12′ is controlled to 50 nm, for example. The sputtering power is controlled to 200 W, and the gas pressure is controlled to 5 mTorr in this example.

Referring to FIG. 2C, the a-Si film 12′ is thermally processed in a furnace or using excimer laser annealing (ELA) to obtain a polycrystalline silicon (p-Si) film 12, which can be referred to as the silicon channel layer as in FIG. 1. ELA is preferred as a thermal processing method for the a-Si film 12′.

When a plastic substrate, not glass, is used as the substrate 10 of the TFT, the temperature at which the a-Si film 12′ is thermally processed has to be properly controlled to prevent deformation of the substrate by heat applied during the thermal process.

Referring to FIG. 2D, the SiO₂ film 13a, which is part of the gate insulating layer 13, is formed on the p-Si film 12. The SiO₂ film 13a may be formed using inductively coupled plasma chemical vapor deposition (ICP-CVD), plasma enhanced CVD (PE-CVD), sputtering, etc. to a thickness of 10 nm or less.

Referring to FIG. 2E, the HfOₓ film 13b, which is part of the gate insulating layer 13 and may be a HfO₂ film is formed on the SiO₂ film 13a using CVD, sputtering, etc. Here, the thickness of the HfO₂ film 13b is controlled to 50 nm or less in this example. The process for forming the HfOₓ film 13b is performed at a low temperature of 500□ or less in this example.

Referring to FIG. 2F, the gate 14 is formed of, for example, Al, on the gate insulating layer 13. The gate insulating layer 13 and the gate 14, which are not properly shaped to perform their function, are patterned into final shapes in subsequent processes.

Referring to FIG. 2G, the gate 14 and the gate insulating layer 13 are etched using a first mask M1 by dry etching. The mask M has a pattern corresponding to the shape of the gate 14. The gate 14 is patterned according to the pattern of the first mask M1, and the gate insulating layer 13 under the gate 21 is also patterned to the same shape. As a result, a portion of the p-Si film 12 not covered by the gate 14 is exposed.

Referring to FIG. 2H, the portion of the p-Si film 12 not covered by the gate 21 are doped using ion shower doping, and then activated by a 308-nm XeCl excimer laser.

Referring to FIG. 21, the portion of the p-Si film 12 not covered by the gate 21 is patterned using a second mask M2 by dry etching to form the source region 12a and the drain region 12b. An undoped p-Si region remains under the gate 14 and functions as a channel.

Referring to FIG. 2J, a third SiO₂ insulating layer 15 as an ILD is formed on the stack of the layers formed above using ICP-CVD, PE-CVD, or sputtering to a thickness of about 3000 Å.

Referring to FIG. 2K, a source contact hole 15a and a gate contact hole 15b are formed in the third SiO₂ insulating layer 15 using a third mask M3.

Referring to FIG. 2L, the source electrode 16 and the drain electrode 17 are formed in the source contact hole 15a and the gate contact hole 15b to obtain a desired TFT.

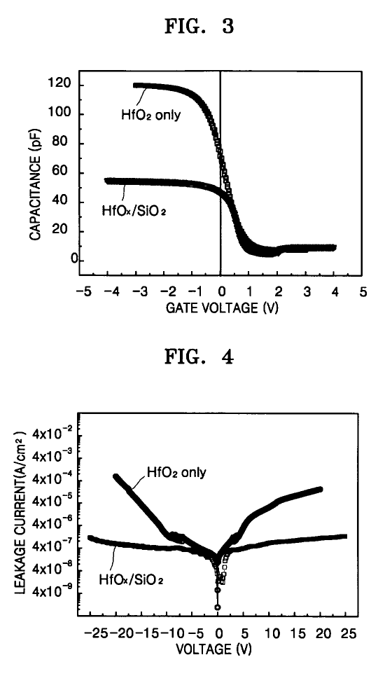

FIG. 3 is a graph of gate voltage versus gate capacitance showing the characteristics of the TFT according to the present disclosure. Sample 1 having a gate insulating layer which is a stack of a HfO₂ film (500 Å) and a SiO₂ film (100 Å) on a Si substrate, and Sample 2 having a gate insulating layer which is a single HfO₂ film (500 Å) were manufactured for testing. The HfO₂ film was formed in the following conditions.

1) Power: 30 W, 15 minutes

2) Gas: Ar, 20 sccm

3) Processing pressure: 0.8 mTorr

4) Oxidation (furnace): 500□/4 hr

5) Annealing: rapid thermal annealing (RTA) 500□/1 min./N₂

FIG. 4 is a graph of the voltage-leakage current characteristics of the two samples manufactured above. The electric characteristics of Sample 1 according to the present disclosure and Sample 2 as a comparative example are as follows.

Sample 1:

Vfb=0.62V, Cox=55 pF, EOT=138 Å, J=3.58×10⁻⁷ (A/cm²) (@−5V)

Sample 2:

Vfb=0.64V, Cox=120 pF, EOT=68 Å, J=6.3×10⁻⁷ (A/cm²) (@−5V)

According to the results in FIGS. 3 and 4, the gate insulating layer according to the present disclosure, which has a stacked structure of HfOₓ/SiO₂ films, has a reduced current leakage characteristic and a high capacitance.

As described above, a TFT according to the present disclosure including a gate insulating layer having the stacked structure described above has improved interface property and thus a low leakage current.

The TFT according to the present disclosure can be formed on a silicon substrate, a glass substrate, or a plastic substrate which is weak to heat.

In addition, the TFT according to the present disclosure is suitable to be used in a flat panel display device, for example, an active matrix liquid crystal display (AMLCD), an active matrix organic light emitting diode (AMOLED), a solar battery, a semiconductor memory device, etc.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A silicon thin film transistor (TFT) comprising:
a substrate;
a silicon channel layer formed on the substrate with a source and a drain on both sides thereof;
a gate insulating layer formed on the silicon channel layer; and
a gate formed on the gate insulating layer,
wherein the gate insulating layer includes an HfOₓ film.

2. The TFT of claim 1, wherein the gate insulating layer includes a HfOₓ film and a SiO₂ film.

3. The TFT of claim 1, wherein the silicon channel layer is formed of polycrystalline silicon.

4. The TFT of claim 2, wherein the silicon channel layer is formed of polycrystalline silicon.

5. The TFT of claim 3, wherein the HfOₓ film has a thickness of 50 nm or less.

6. The TFT of claim 4, wherein the HfOₓ film has a thickness of 50 nm or less.

7. The TFT of claim 1, wherein the HfOₓ film has a thickness of 50 nm or less.

8. The TFT of claim 2, wherein the HfOₓ film has a thickness of 50 nm or less.

9. The TFT of claim 3, wherein the SiO₂ film has a thickness of 10 nm or less.

10. The TFT of claim 4, wherein the SiO₂ film has a thickness of 10 nm or less.

11. The TFT of claim 1, wherein the SiO₂ film has a thickness of 10 nm or less.

12. The TFT of claim 2, wherein the SiO₂ film has a thickness of 10 nm or less.
